(19) United States
(12) Patent Application Publication
(10) Pub. No.: US 2025/0218838 A1
(43) Pub. Date: Jul. 3, 2025

(54) APPARATUS AND METHOD OF PROCESSING A SUBSTRATE

(71) Applicant: SEMES CO., LTD., Cheonan-si (KR)

(72) Inventors: Jun Hyun LIM, Seoul (KR); Jun Young CHOI, Cheongju-si (KR); Hee Jun YOUN, Goyang-si (KR); Eun Jung LEE, Seoul (KR); Seul Gi CHOI, Busan (KR)

(73) Assignee: SEMES CO., LTD., Cheonan-si (KR)

(21) Appl. No.: 19/005,111

(22) Filed: Dec. 30, 2024

(30) Foreign Application Priority Data
Dec. 29, 2023 (KR) 10-2023-0196197

(51) Int. Cl. H01L 21/677; B08B 3/04; B08B 3/08; H01L 21/67

(52) U.S. Cl. CPC H01L 21/67745; B08B 3/041; B08B 3/08; H01L 21/67057

(57) ABSTRACT

The present invention provides an apparatus of processing a substrate. The apparatus of processing a substrate includes: a gripping unit gripping a plurality of substrates on both sides; a body supporting the gripping unit; an actuating unit moving and rotating the gripping unit with respect to the body; and a control unit controlling the actuating unit, wherein the actuating unit includes: a horizontal actuating unit horizontally moving the gripping unit in a first direction with respect to the body; a rotation actuating unit rotating the gripping unit with respect to the body.

### CROSS-REFERENCE TO RELATED APPLICATIONS

This application claims priority to and the benefit of Korean Patent Application No. 10-2023-0196197 filed in the Korean Intellectual Property Office on Dec. 29, 2023, the entire contents of which are incorporated herein by reference.

### TECHNICAL FIELD

The present invention relates to an apparatus and method of processing a substrate and, in more detail, an apparatus and method of processing a substrate, the apparatus and method processing a substrate by immersing the substrate into treatment liquid.

### BACKGROUND ART

In order to manufacture a semiconductor, a desired pattern is formed on a substrate such as a wafer through various processes such as photographing, etching, ashing, ion injection, and thin film deposition. Various treatment liquids and treatment gases are used in each of the processes, and particles and process byproducts are produced during the processes. A liquid treatment process is performed on a substrate before and after each process to remove a thin film, particles, and process byproducts on the substrate from the substrate. In general, a liquid treatment process treats a substrate with a chemical, and then removes the chemical on a substrate with a rinse solution and then performs drying treatment.

As a method of treating a substrate with treatment liquid such as a chemical and/or a rinse solution, there is a batch-type treatment method that treats a plurality of substrates in a vertical posture in batch. The batch-type treatment method performs substrate treatment by immersing a plurality of substrates in a vertical posture in batch into a treatment bath in which a chemical or a rinse solution is stored. Since substrates are immersed in a vertical posture, when the pattern formed on a substrate has a high aspect ratio, pattern leaning may be generated in the pattern formed on the substrate in processes including a process of lifting the patterns from the treatment bath. Further, when drying treatment is performed within a short time with a plurality of substrates exposed to the air at a time, there may be a possibility that a water mark is generated on some of the plurality of substrates. Accordingly, a method of changing the vertical posture of substrates into a horizontal posture in a treatment bath is being studied, but a wide space is required to change the posture of substrates immersed in treatment liquid in a treatment bath, so there is a problem that the size of a treatment bath is increased and particles due to friction of an actuating unit contaminate the treatment bath and substrates in rotation.

### SUMMARY OF THE INVENTION

An objective of the present invention is to provide an apparatus and method of processing a substrate, the apparatus and method being able to efficiently perform liquid treatment on substrates.

An objective of the present invention is to provide an apparatus and method of processing a substrate, the apparatus and method being able to change a posture substrates immersed in treatment liquid.

An objective of the present invention is to provide an apparatus and method of processing a substrate, the apparatus and method being able to minimize production of particles in a process of changing the posture of substrates.

An objective of the present invention is to provide an apparatus and method of processing a substrate, the apparatus and method being able to minimize contamination of substrates in a process of changing the posture of substrates.

The present invention provides an apparatus of processing a substrate. The apparatus for treating a substrate includes: a gripping unit gripping a plurality of substrates on both sides; a body supporting the gripping unit; an actuating unit moving and rotating the gripping unit with respect to the body; and a control unit controlling the actuating unit, wherein the actuating unit comprises: a horizontal actuating unit horizontally moving the gripping unit in a first direction with respect to the body; and a rotation actuating unit rotating the gripping unit with respect to the body.

In an embodiment, wherein the rotation actuating unit comprises: a rotary shaft provide to be horizontally movable in the first direction and rotating about a center axis; and an actuator rotating the rotary shaft, and a longitudinal direction of the rotary shaft is provided in a direction perpendicular to the first direction when seen from above.

In an embodiment, wherein the body further comprises guides guiding horizontal movement of the rotary shaft in the first direction.

In an embodiment, wherein the body further comprises: a base; a first side plate; and a second side plate, the guides are provided as slits formed at the first side plate and the second side plates, respectively, and the rotary shaft is inserted in the slits to be horizontally movable between a first position and a second position along the slits.

In an embodiment, wherein the gripping unit comprises: a gripping member gripping the plurality of substrates; and a support extending upward from the gripping member and fixedly coupled to the rotary shaft.

In an embodiment, wherein the actuating unit further comprises an elevation actuating unit moving up and down the body in a vertical direction.

In an embodiment, further comprising a treatment bath having an receiving space in which treatment liquid is accommodated, and performing liquid treatment by immersing the plurality of substrates in the treatment liquid, wherein the control unit performs control to perform a posture changing of the plurality of substrates gripped by the gripping unit between a horizontal posture and a vertical posture.

In an embodiment, wherein the control unit performs control such that the posture changing is made with the plurality of substrates immersed in the treatment liquid accommodated in the treatment bath.

In an embodiment, wherein the control unit controls the actuating unit such that rotation of the gripping unit and the horizontal movement of the gripping unit are simultaneously made when the posture changing is performed.

In an embodiment, wherein the control unit controls the actuating unit such that the actuating unit is not immersed in the treatment liquid accommodated in the treatment bath when the posture changing is performed.

Further, the present invention provides a method of processing a substrate. The method of processing a substrate includes: a treating step of performing liquid treatment by immersing a plurality of substrates in a vertical posture in a treatment bath accommodating treatment liquid; and a posture changing step of changing a posture of the plurality of substrates from the vertical posture to a horizontal posture after the treating step, wherein, in the posture changing step, when the plurality of substrates is rotated from the vertical posture to the horizontal posture, horizontal movement of the plurality of substrates is also performed.

In an embodiment, wherein vertical movement of the plurality of substrates accompanies in the posture changing step.

In an embodiment, wherein posture changing of the plurality of substrates is made in the treatment bath in the posture changing step.

In an embodiment, wherein the posture changing step is made with the plurality of substrates immersed in the treatment liquid.

In an embodiment, wherein the posture changing step is made while the actuation unit performing the posture changing is not immersed in the treatment liquid.

In an embodiment, further comprising a substrate transferring step of transferring the plurality of substrates after the posture changing step.

Further, the present invention provides an apparatus of processing a substrate. The apparatus for treating a substrate includes: a first treatment bath having an receiving space in which first treatment liquid is accommodated, and performing liquid treatment by immersing a plurality of substrates in the first treatment liquid; a second treatment bath having an receiving space in which second treatment liquid is accommodated, and performing liquid treatment by immersing a plurality of substrates in the second treatment liquid; a transfer robot transferring the plurality of substrates; and a control unit controlling the transfer robot, wherein the transfer robot comprises: a gripping unit gripping a plurality of substrates on both sides; a body supporting the gripping unit; and an actuating unit moving and rotating the gripping unit with respect to the body, the actuating unit comprises: a horizontal actuating unit horizontally moving the gripping unit in a first direction with respect to the body; a rotation actuating unit rotating the gripping unit with respect to the body; and an elevation actuating unit moving up and down the body in a vertical direction, and the control unit performs control to change a posture of the plurality of substrates gripped by the gripping unit between a horizontal posture and a vertical posture in the first treatment bath and the second treatment bath.

In an embodiment, wherein the rotation actuating unit comprises: a rotary shaft provide to be horizontally movable in the first direction and rotating about a center axis; and an actuator rotating the rotary shaft, a longitudinal direction of the rotary shaft is provided in a direction perpendicular to the first direction when seen from above, the body comprises: a base; a first side plate; a second side plate; and guides guiding horizontal movement of the rotary shaft in the first direction, the guides are provided as slits formed at the first side plate and the second side plates, respectively, and the rotary shaft is inserted in the slits to be horizontally movable between a first position and a second position along the slits.

In an embodiment, wherein the control unit controls the actuating unit such that rotation of the gripping unit and the horizontal movement of the gripping unit are simultaneously made when the posture changing is performed.

In an embodiment, wherein the control unit controls the actuating unit such that the posture changing is made with the plurality of substrates immersed in the first treatment liquid or the second treatment liquid accommodated in the first treatment bath or the second treatment bath and such that the actuating unit is not immersed in the first treatment liquid or the second treatment liquid accommodated in the first treatment bath or the second treatment bath when the posture changing is performed.

Effects of the present invention are not limited to those described above and effects not stated above will be clearly understood to those skilled in the art from the specification and the accompanying drawings.

### BRIEF DESCRIPTION OF THE DRAWINGS

FIG. 1 is a schematic view of an apparatus of processing a substrate according to an embodiment of the present invention seen from above.

FIG. 2 is a view schematically showing the structure of the second chemical liquid bath of FIG. 1.

FIG. 3 is a perspective view showing an example of the second batch transfer unit of FIG. 1.

FIG. 4 is a flowchart according to an embodiment of a method of processing a substrate of the present invention.

FIG. 5 shows the appearance of the second chemical liquid bath of FIG. 1 when the treating step of FIG. 4 is performed.

FIG. 6 to FIG. 9 show the appearance of the second chemical liquid bath of FIG. 1 when the first posture changing step of FIG. 4 is performed.

FIG. 10 shows that a second batch transfer unit transfers substrates from the second chemical liquid bath to a second rinse bath.

FIG. 11 to FIG. 13 schematically show a process in which the second posture changing step of FIG. 4 is performed in the second rinse bath.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Further, components that transfer substrates W to be described below, for example, transfer units or transfer robots may be referred to as transfer modules.

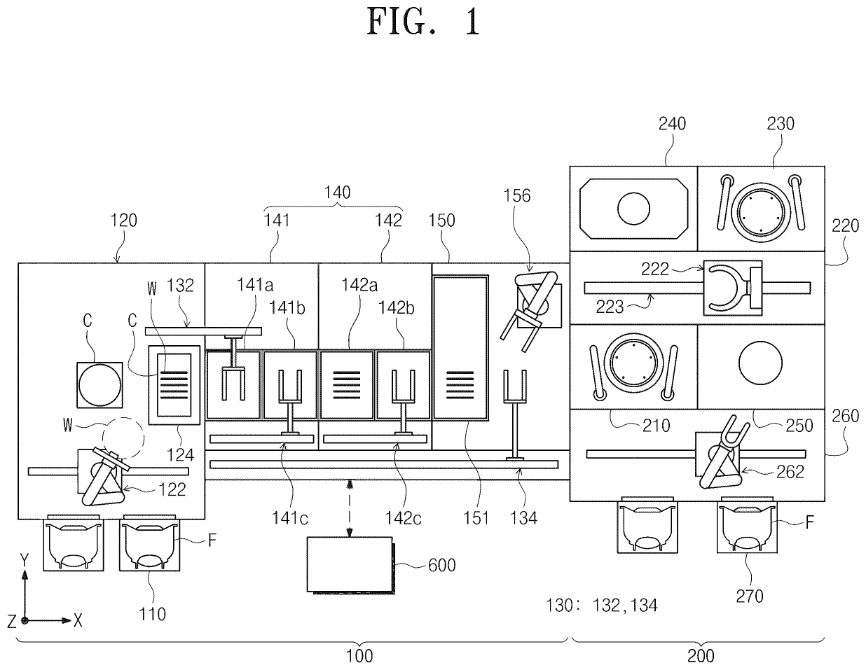

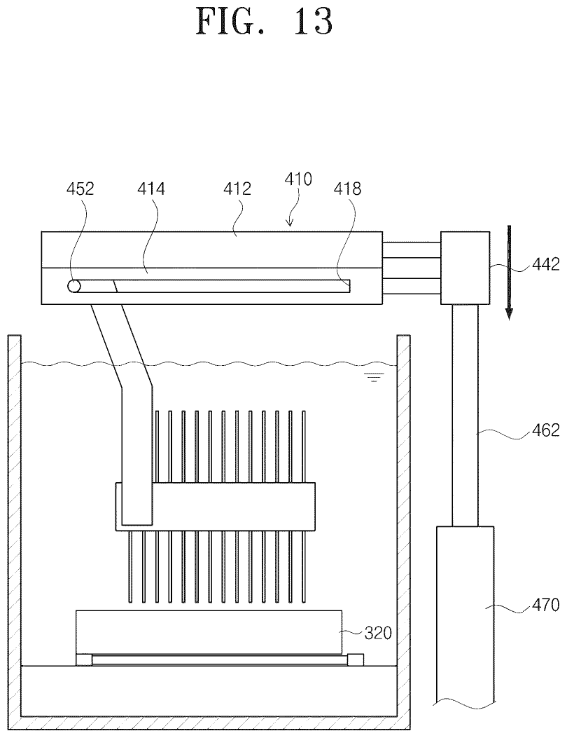

Hereafter, embodiments of the present invention are described with reference to FIG. 1 to FIG. 13.

FIG. 1 is a schematic view of an apparatus of processing a substrate according to an embodiment of the present invention seen from above.

Referring to FIG. 1, an apparatus 10 of processing a substrate may include a first process performing part 100, a second process performing part 200, and a control unit 600. The first process performing part 100 and the second process performing part 200 may be arranged in a line when seen from above. Hereafter, the direction in which the first process performing part 100 and the second process performing part 200 are arranged is referred to as a first direction X, a direction perpendicular to the first direction X when seen from above is referred to as a second direction Y, and a direction perpendicular to the first direction X and the second direction Y is referred to as a third direction Z.

The first process performing part 100 can perform liquid treatment on a plurality of substrates W all at once in a batch type. For example, liquid treatment may be washing treatment that removes unnecessary films or particles on a substrate W. The first process performing part 100 can simultaneously treat a plurality of substrates W with a pattern surface of the substrates W in a direction perpendicular to the ground.

The first process performing part 100 may include a first load port unit 110, an index chamber 120, a transfer unit 130, a liquid treatment chamber, and a posture changing unit 150.

The first load port unit 110 may include at least one or more load ports. A conveying container F in which a substrate W is accommodated may be placed in the first load port unit 110. A plurality of substrates W may be accommodated in the conveying container F. For example, 25 sheets of substrates W may be accommodated in the conveying container F. The conveying container F may be a cassette, a FOD, or a FOUP. The conveying container F can be loaded into the first load port unit 110 by a container transfer device. The substrates W accommodated in the conveying container F that is placed in the first load port unit 110 may be non-treated substrates W. The non-treated substrates W, for example, may be substrates W that have not been treated or substrates W that have been partially treated but require liquid treatment.

Further, a container F in which non-treated substrates W are accommodated can be placed in the first load port unit 110. That is, the first load port unit 110 can serve to load substrates W that require treatment.

The first load port unit 110 may be coupled to the index chamber 120. The index chamber 120 and the first load port unit 110 may be arranged in the second direction Y. The first index chamber 120 may include an index robot 122 and a posture changing unit 124. The index robot 122 can unload substrates W that have not been treated or require treatment from the container F seated in the first load port unit 110. The first transfer robot 122 can unload substrates W from the container F and load the substrates W into an accommodation container C provided in the first index chamber 120. The first transfer robot 122 may have a batch hand that can simultaneously hold and transfer a plurality of sheets (e.g. 25 sheets) of substrates W.

The accommodation container C may have a substantially cylindrical shape. The accommodation container C may have an receiving space therein. A plurality of substrates W may be accommodated in the receiving space of the accommodation container C. For example, 50 sheets of substrates W may be accommodated in the receiving space of the accommodation container C. The accommodation container C may have a cylindrical shape of which at least two or more surfaces of the surfaces thereof are open. A supporting member that supports/holds substrates W may be provided in the receiving space of the accommodation container C.

When substrates W unloaded from the conveying container F finish being loaded into the accommodation container C, the substrates w can be transferred to the posture changing unit 124 disposed in the index chamber 120 by a transfer part not shown. The posture changing unit 124 can rotate the accommodation container C. For example, the posture changing unit 124 can rotate the accommodation container C such that an open portion of the accommodation container C faces up. When the accommodation container C is rotated such that an open portion faces up, the posture of the substrates W accommodated in the accommodation container C can be changed from a horizontal posture to a vertical posture. The horizontal posture may means that the upper surface of a substrate (for example, a surface having a pattern formed thereon) is parallel with an X-Y plane (i.e., the ground) and the vertical position may mean that the upper surface of a substrate W is parallel with an X-Z plane or a Y-Z plane (i.e., a surface perpendicular to the ground).

The transfer unit 130 may include a first transfer unit 132 transferring substrates W between the index chamber 120 and a batch treatment unit 140 and a second transfer unit 134 transferring substrates W between the batch treatment unit 140 and the posture changing unit 150 to be described below.

The first transfer unit 132 may include a rail extending in the first direction X and a hand configured to be able to transfer a plurality of substrates W at a time. The first transfer unit 132 can hold substrates W changed in posture at the posture changing unit 124 and transfer the held substrates W to a liquid treatment chamber. For example, the first transfer unit 132 can transfer substrates W changed in posture at the posture changing unit 124 to any one treatment bath selected from batch treatment baths 141a to 142b of the batch treatment unit 140. The second transfer unit 134 may include a rail extending in the first direction X and a hand configured to be able to transfer a plurality of substrates W at a time.

The second transfer unit 134 may be configured to be able to transfer substrates W between a first batch treatment unit 141 and a second batch treatment unit 142 of the batch treatment unit 140 to be described below. Further, the second transfer unit 134 may be configured to be able to transfer substrates W between the batch treatment unit 140 and the posture changing unit 150.

The liquid treatment chamber performs liquid treatment on substrates W by supplying treatment liquid.

According to an example, the liquid treatment chamber is provided as the batch treatment unit 140 that performs liquid treatment on a plurality of substrates W at a time. Liquid treatment can be performed on a plurality of substrates W at a time using treatment liquid in the batch treatment unit 140. The treatment liquid that is used in the batch treatment unit 140 may be a chemical and/or a rinse solution. For example, the chemical may be a chemical that has the property of strong acid or strong base. For example, the chemical may be appropriately selected from an Ammonia-Hydrogen Peroxide Mixture (APM), a Hydrochloricacid-Hydrogen Peroxide Mixture (HPM), a Hydrofluoricacid-Hydrogen Peroxide Mixture (FPM), Diluted Hydrofluoric acid (DHF), Diluted Sulfuric acid Peroxide (DSP), a chemical removing SiN, a chemical containing phosphoric acid, a chemical containing sulfuric acid, or the like. The rinse solution may be water. For example, the rinse solution may be pure water.

The batch treatment unit 140 may include a first batch treatment unit 141 and a second batch treatment unit 142.

The first batch treatment unit 141 and the second batch treatment unit 142 each include a chemical liquid bath, a rinse bath, and a batch transfer unit transferring substrates W between them.

In each batch treatment unit, substrates W are treated with first treatment liquid in the chemical liquid bath and then treated with second treatment liquid in the rinse bath. The first treatment liquid may be a chemical and the second treatment liquid may be a rinse solution.

Substrates W changed in posture by the posture changing unit 124 and accommodated in the accommodation container C and substrates W accommodated in the batch treatment bath of the batch treatment unit 140 may be arranged in parallel in the second direction Y when seen from above.

Further, substrates W accommodated in the batch treatment baths 141a to 142b of the batch treatment unit 140 and substrates W accommodated in a posture changing bath 151 of the posture changing unit 150 may be arranged in parallel in the second direction Y when seen from above. Further, substrates W accommodated in the batch treatment baths 141a to 142b of the batch treatment unit 140 may be arranged in parallel in the second direction Y when seen from above.

The first batch treatment unit 141 may include a first chemical liquid bath 141a, a first rinse bath 141b, and a first batch transfer unit 141c.

It is possible to simultaneously perform liquid treatment on a plurality of substrates W with a chemical such as DHF in the first chemical liquid bath 141a. It is possible to simultaneously perform liquid treatment on a plurality of substrates W with a rinse solution in the first rinse bath 141b. However, the present invention is not limited thereto and the treatment liquid that is used in the first chemical liquid bath 141a may be variously changed to treatment liquid selected from the treatment liquids described above.

Thin films on substrates W, remaining films on the substrates W, foreign substances on the substrates W, or the like can be removed in the first chemical liquid bath 141a. It is possible to simultaneously treat a plurality of substrates W with a rinse solution such as pure water in the first rinse bath 141b. A chemical remaining on substrates W after used to treat the substrates W in the first chemical liquid bath 141a is removed from the substrates W in the first rinse bath 141b.

The first batch transfer unit 141c may be configured to be able to transfer substrates W between the first chemical liquid bath 141a and the first rinse bath 141b.

The second batch treatment unit 142 may include a second chemical liquid bath 142a, a second rinse bath 142b, and a second batch transfer unit 142c.

It is possible to simultaneously perform liquid treatment on a plurality of substrates W with a chemical containing phosphoric acid in the second chemical liquid bath 142a. It is possible to simultaneously treat a plurality of substrates W with a rinse solution in the second rinse bath 142b. However, the present invention is not limited thereto and the treatment liquid that is used in the second chemical liquid bath 142a may be variously changed to treatment liquid selected from the treatment liquids described above.

The second batch transfer unit 142c may be configured to be able to transfer substrates W between the second chemical liquid bath 142a and the second rinse bath 142b.

According to an embodiment, the first batch treatment unit 141 can treat substrates W with a chemical different from that in the second batch treatment unit 142. Hereafter, it is exemplified that the second batch treatment unit 142 treats substrates W with a phosphoric acid solution and the first batch treatment unit 141 treats substrates W with any one chemical of the chemicals exemplified above.

It is shown in FIG. 1 that the batch treatment unit 140 includes the first batch treatment unit 141 and the second batch treatment unit 142, but the present invention is not limited thereto.

For example, additional batch treatment units may be further provided. Additional batch treatment units can treat substrates W with a chemical the same as or different from that of the first batch treatment unit 141 and the second batch treatment unit 142.

Selectively, the batch treatment unit 140 may include only the second batch treatment unit 142 without the first batch treatment unit 141.

Hereafter, the structure of the batch treatment unit 140 is described.

The first batch treatment unit 141 and a second batch treatment unit 142 are provided in the same or similar structures. The following describes the second batch treatment unit 142 as the main focus.

The second batch treatment unit 142 may include a second chemical liquid bath 142a, a second rinse bath 142b, and a second batch transfer unit 142c.

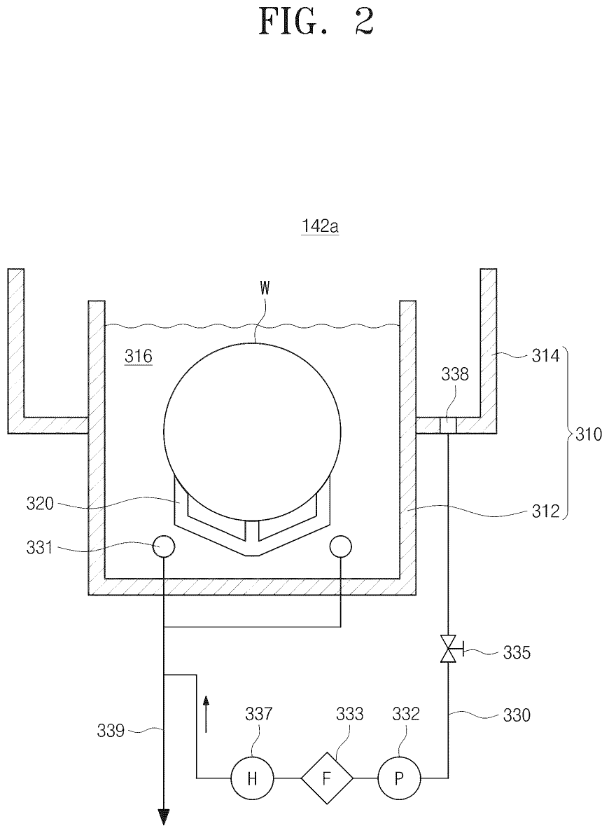

FIG. 2 is a view schematically showing the structure of the second chemical liquid bath of FIG. 1.

The second chemical liquid bath 142a has a treatment bath 310, a supporting unit 320, a circulation line 330, and a liquid supply pipe 331.

The treatment bath 310 may have an inner bath 312 and an outer bath 314. The inner bath 312 has an receiving space 316 therein. The inner bath 312 may have a cylindrical shape with an open upper portion. For example, the inner bath 312 may have a rectangular prism shape. Treatment liquid may be accommodated in the receiving space 316.

The outer bath 314 is provided to surround the inner bath 312 outside the inner bath 312. For example, the outer bath 314 has a rectangular prism shape similar to the inner bath 312. The outer bath 314 is provided in a size larger than the inner bath 312. The outer bath 314 accommodates treatment liquid overflowing from the inner bath 312. A discharge hole 338 for discharging treatment liquid is formed at the outer bath 314. The discharge hole 338 is formed through the bottom of the outer bath 314. Treatment liquid overflowing from the inner bath 312 to the outer bath 314 is discharged to the circulation line 330 to be described below through the discharge hole 338.

The supporting unit 320 is disposed in the receiving space 316 and can support a substrate W. The supporting unit 320 may be configured to be able to support a plurality of substrates W. For example, the supporting unit 320 may be configured to be able to support 50 sheets of substrates W. The supporting unit 320 may be formed such that a pair of rod-shaped bodies is disposed to face each other and a supporting groove (not shown) in which a substrate W can be supported is formed at each of the bodies.

The circulation line 330 circulates treatment liquid in the treatment bath 310.

A liquid supply pipe 331, a pump 332, a filter 333, a valve 335, and a heater 337 are installed in the circulation line 330. The pump 332 provides dynamic pressure to treatment liquid such that a phosphoric acid solution circulates along the circulation line 330.

The liquid supply pipe 331 supplies treatment liquid to the treatment bath 310. The liquid supply pipe 331 is disposed in the treatment bath 310.

A plurality of liquid supply pipes 331 may be provided. In this case, the liquid supply pipes 331 may be disposed in parallel with each other.

The filter 333 removes foreign substances in treatment liquid circulating in the circulation line 330.

The valve 335 opens and closes the circulation line 330. When the valve 335 is opened, treatment liquid in the treatment bath 310 keeps circulating along the circulation line 330.

The heater 337 can heat treatment liquid that is supplied to the treatment bath 310 to a set temperature.

The second rinse bath 142b may have a structure similar to the second chemical liquid bath 142a. For example, the second rinse bath 141 also includes a treatment bath 310 having an receiving space 316 and treatment liquid can be accommodated in the receiving space 316.

The second rinse bath 142b, unlike the second chemical liquid bath 142a, includes treatment bath 310 having the receiving space 316 and may be composed of only an inner bath 312 without an outer bath 314.

The second batch transfer unit 142c may be configured to be able to change the posture of substrates and transfer the substrates W between the second chemical liquid bath 142a and the second rinse bath 142b.

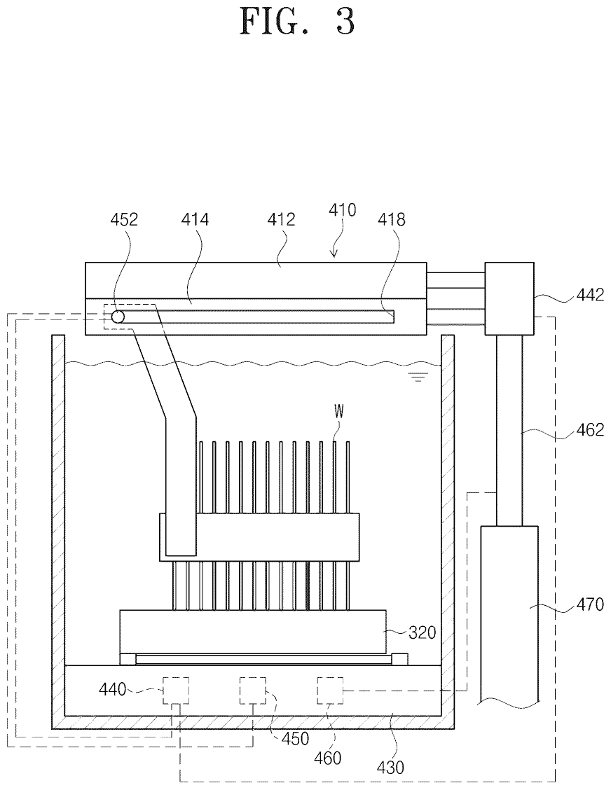

FIG. 3 is a perspective view showing an example of the second batch transfer unit of FIG. 1.

In FIG. 3 and the figures after FIG. 3, the treatment bath 310 is simply represented in a cylindrical shape with an open upper portion.

Referring to FIG. 3, the second batch transfer unit 142c includes a body 310, a holder 420, an actuating unit 430, and a base 470.

The body 410 includes a top plate 421, a first side plate 414, a second side plate 416, and a guide 418.

The top plate 412 is provided substantially in a rectangular plate shape. The first side plate 414 and the second side plate 416 are coupled to face each other to both sides of the top plate 412, respectively. A side of the top plate 412 is coupled to a rotary shaft 452 to be described below, so it is moved up and down by up-down movement of the rotary shaft 452.

The first side plate 414 and the second side plate 416 are provided to face each other with the top plate 412 therebetween and include a guide 418. The guides 418 are slits formed at the first side plate 414 and the second side plate 416, respectively, such that the rotary shaft 452 can be inserted and horizontally moved in the guides 418 of the first side plate 414 and the second side plate 416. The guides 418 may be long slits horizontally formed in one direction. For example, the guides 418 are formed as long slits parallel with the second direction Y and can guide horizontal movement of the rotary shaft 452.

The gripping unit 420 grips a plurality of substrates W. The gripping unit 420 includes a support 422 and a gripping member 424.

The gripping member 424 is provided to be able to support and grip the side of a substrate. The gripping member 424 has a first gripper 424a and a second gripper 424b. The first gripper 424a and the second gripper 424b are spaced apart from each other.

The first gripper 424a and the second gripper 424b have the same structure. Slots 424c in which the edges of substrates W are inserted, respectively, are formed at the grippers 424a and 424b, respectively, in the longitudinal direction thereof. About 50 slits may be formed. Since the edges of substrates W are inserted in the slots 424c of the gripping member 424 and the gripping member 424 grips both sides of the substrates W, the gripping member 424 can stably grip the substrates W even though the gripping unit 420 is rotated and moved.

An end of each of the gripper 424a and 424b is coupled and fixed to the support 422. For example, the first gripper 424a may be fixedly coupled to a first support 422a and the second gripper 424b may be fixedly coupled to the second support 422b. The gripping member 424 and the support may be fixedly coupled at an angle of about 90 degrees.

An end of the support 422 is coupled to the gripping member 424 and extends upward from the gripping member 424 and another end is fixedly coupled to the rotary shaft 452 inserted in the guides 418. When the rotary shaft 452 is rotated or horizontally moved, the support 422 is rotated or horizontally moved.

Though not shown, the gripping unit 420 may include a separate actuating unit (not shown) and the actuating unit (not shown) can move the gripping member 424 at a position where the gripping member 424 holds substrates W by gripping the sides of the substrates W or is spaced apart from substrates W. For example, the actuating unit (not shown) can rotate the holding member 424 about an axis that is parallel with the second direction Y.

The actuating unit 430 moves the body 410 or moves and rotates the gripping unit 420. The actuating unit 430 includes a horizontal actuating unit 440, a rotation actuating unit 550, and an elevation actuating unit 560.

The horizontal actuating unit 440 horizontally moves the gripping unit 420 in one direction with respect to the body 410. For example, the horizontal actuating unit 4440 includes a horizontal actuator 442 and the horizontal actuator 442 can horizontally moves the rotary shaft 452 to be described below in a direction parallel with the second direction Y along the guide 418 between a first position and a second position. The first position is the position when the rotary shaft 452 is at an end of the guides 418 and the second position is the position when the rotary shaft 452 is at another end of the guides 418. The horizontal actuator 442 may include a motor.

The rotation actuating unit 450 rotates the gripping unit 420 with respect to the body 410. The rotation actuating unit 450 includes the rotary shaft 452 and a rotation actuator 454.

The rotary shaft 452 may be provided as a cylindrical shaft and is inserted in the guides 418 formed at the first side plate 414 and the second side plate 416. The rotary haft 452 is fixedly coupled to the support 422. For example, an end of the rotary shaft 452 may be fixedly coupled to a first support 422a and the other end may be fixedly coupled to a second support 422b.

The longitudinal direction of the rotary shaft 452 may be provided perpendicularly to the second direction Y when seen from above. That is, the rotation axis of the rotary shaft 452 may be provided in parallel with the first direction X.

As the rotary shaft 452 is horizontally moved in the second direction Y along the guides 418 and is rotated about the rotation axis that is parallel with the first direction X, the gripping unit 420 coupled to the rotary shaft 452 can be horizontally moved or rotated and substrates W gripped by the gripping unit 420 can be horizontally moved in a direction that is parallel with the second direction Y or can be rotated about a rotation axis that is parallel with the first direction X.

The elevation actuating unit 460 includes an elevation shaft 462 and an elevation actuator 464. An end of the elevation shaft 462 is fixedly coupled to the body 410 and the other end is coupled to a base 470. The base 470 is coupled to a side of the second batch treatment unit 142 and is provided to be able to straightly move in a direction that is parallel with the first direction X.

The elevation actuator 464 moves up and down the elevation shaft 462. When the body 410 is moved up, substrates W gripped by the gripping unit 420 can be moved up and down in the third direction Z.

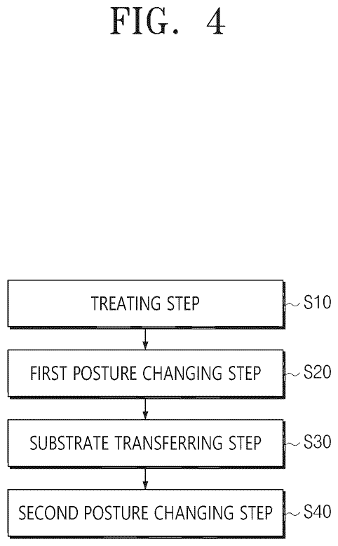

Hereafter, an embodiment of a method of processing a substrate W in the second batch treatment unit in accordance with FIG. 4 to FIG. 13 is described.

FIG. 4 is a flowchart according to an embodiment of a method of processing a substrate of the present invention.

Referring to FIG. 4, a method of processing a substrate W includes a treating step S10, a first posture changing step S20, a substrate transferring step S30, and a second posture changing step S40.

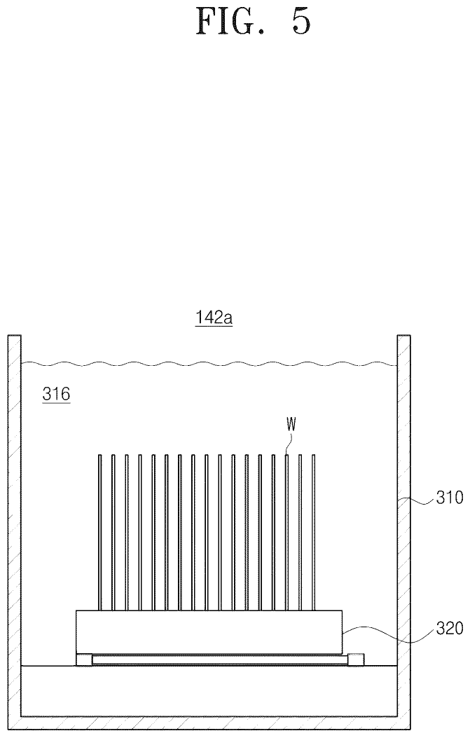

First, the treating step S10 is performed. FIG. 5 shows the appearance of the second chemical liquid bath of FIG. 1 when the treating step of FIG. 4 is performed.

Referring to FIG. 5, in the treating step S10, substrates W are loaded into the treatment bath 310 of the second chemical liquid bath 142a filled with treatment liquid and are delivered to the supporting unit 320 disposed in the receiving space 316. The substrates W are immersed in the treatment liquid in the treatment bath 310.

When treatment by the treatment liquid is finished, the treating step S10 is ended and the first posture changing step S20 is performed.

In the first posture changing step S20, the gripping unit 420 grips the substrates W and changes the posture of the substrates W from a vertical posture to a horizontal posture.

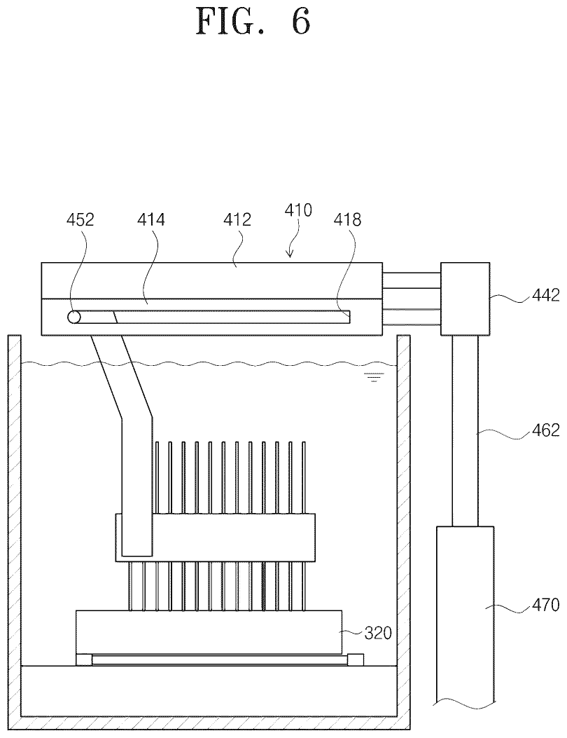

FIG. 6 to FIG. 9 show the appearance of the second chemical liquid bath of FIG. 1 when the first posture changing step of FIG. 4 is performed.

Hereafter, the first posture changing step S20 is described with reference to FIG. 6 to FIG. 9.

At the point of time of end of the treating step S10, the substrates W supported by the supporting unit 320 in the treatment bath 310 are in a vertical posture (a posture in which the upper surfaces or the lower surfaces of the substrates are parallel with a direction perpendicular to the ground). In the first posture changing step S20, a process of changing the posture of the substrates W from the vertical posture to a horizontal posture (a posture in which the upper surfaces or the lower surfaces of the substrates are parallel with the ground). Posture changing is made in the treatment bath 310 and is performed with a plurality of substrates W immersed in the treatment liquid accommodated in the treatment bath 310.

Referring to FIG. 6 to FIG. 9, as shown in FIG. 6, the gripping unit 420 grips the plurality of substrates W. Thereafter, the posture of the substrates W is changed by rotation of the gripping unit 420.

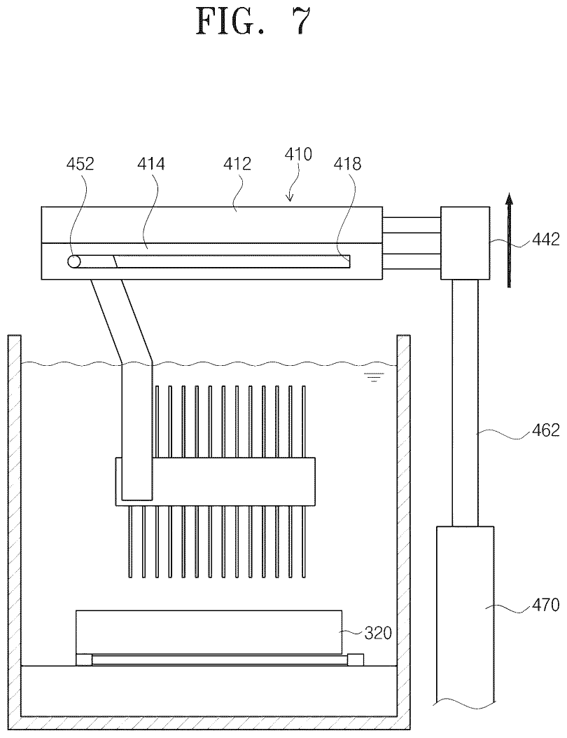

In order to prevent the gripping unit 420 or the substrates W from colliding with the floor of the treatment bath 310 in the rotation process, the actuating unit 430 can move the body 410 vertically upward, as shown in FIG. 7, before rotation of the gripping unit 420.

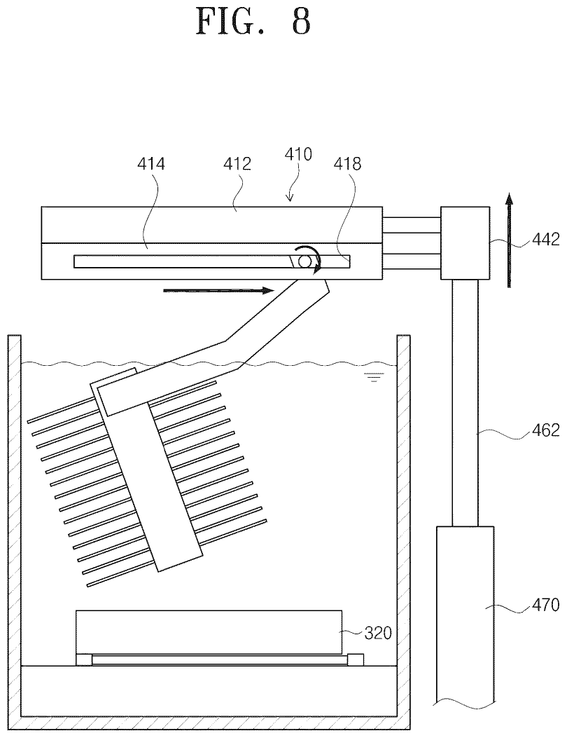

Thereafter, as shown in FIG. 8, the actuating unit 430 rotates the rotary shaft 452, and accordingly, the gripping unit 420 fixedly coupled to the rotary shaft 452 is rotated. In this process, the gripping unit 420 is also horizontally moved.

The horizontal actuator 442 horizontally moves the rotary shaft 452 along the guides 418. Selectively, the body 410 may be moved upward through the elevation actuator 464.

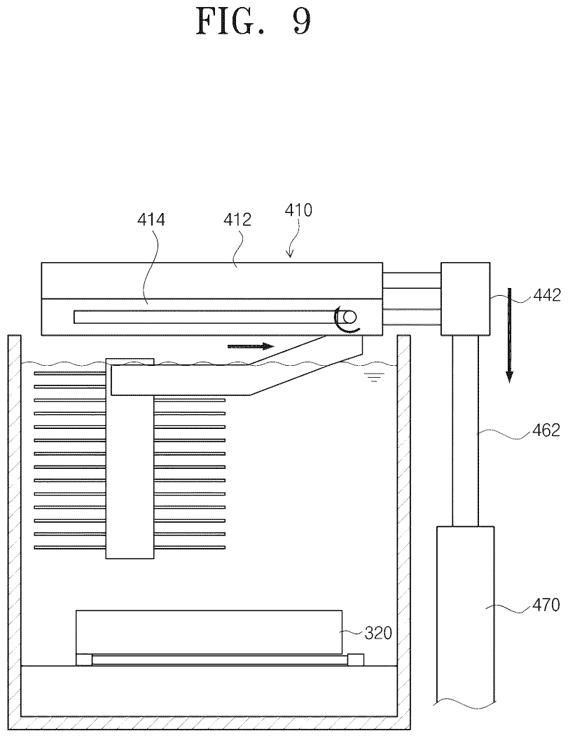

As the rotary shaft 452 is rotated 90 degrees, posture changing of the substrates W from the vertical posture to the horizontal posture is finished. After rotation is finished, the body 410 may be additionally moved downward through the elevation actuator 464. In FIG. 9, the state in which rotation, horizontal movement, and downward movement of the gripping unit 420 have been finished is shown.

As shown in FIG. 6 to FIG. 9, in the process of changing the posture of the substrates W from the vertical posture to the horizontal posture, the actuating unit 430 is not immersed in the treatment liquid accommodated in the treatment bath 310.

The difference between the point in time of end of rotation of the substrates W and the point in time of end of horizontal movement of the substrates W may be a set time or less. For example, the two points in time may be the same points in time. That is, rotation of the substrates W by the rotation actuator 454 may be finished simultaneously with end of horizontal movement of the substrates W.

When posture changing of the substrates W to the horizontal posture is finished, the first posture changing step S20 is ended and the substrate transferring step S30 is performed.

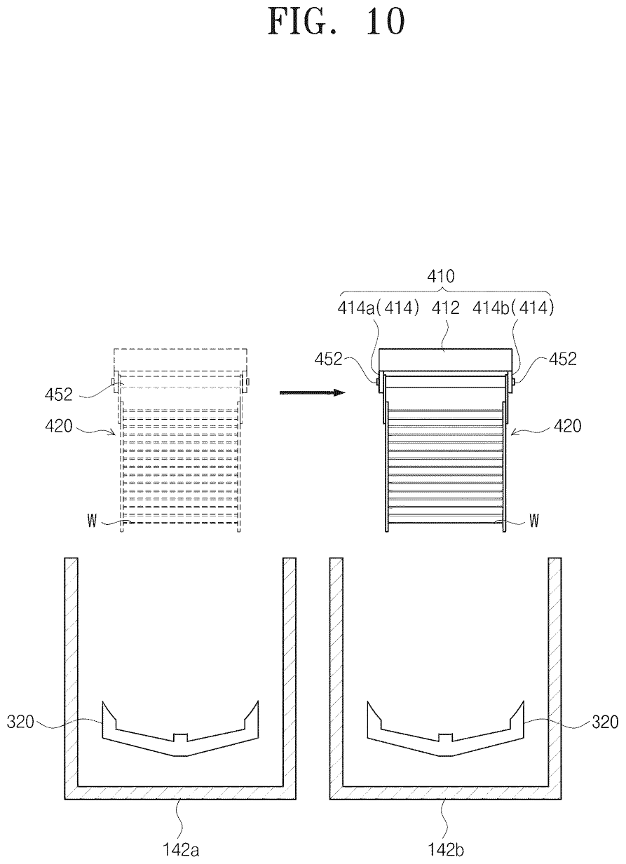

FIG. 10 shows that a second batch transfer unit transfers substrates from the second chemical liquid bath to a second rinse bath.

Referring to FIG. 10, the second batch transfer unit 142c unloads and transfers a plurality of substrates W to the second rinse bath 142b.

When the substrates W are immersed in the treatment liquid accommodated in the second ring bath 142b, the substrate transferring step S30 is ended and the second posture changing step S40 is performed.

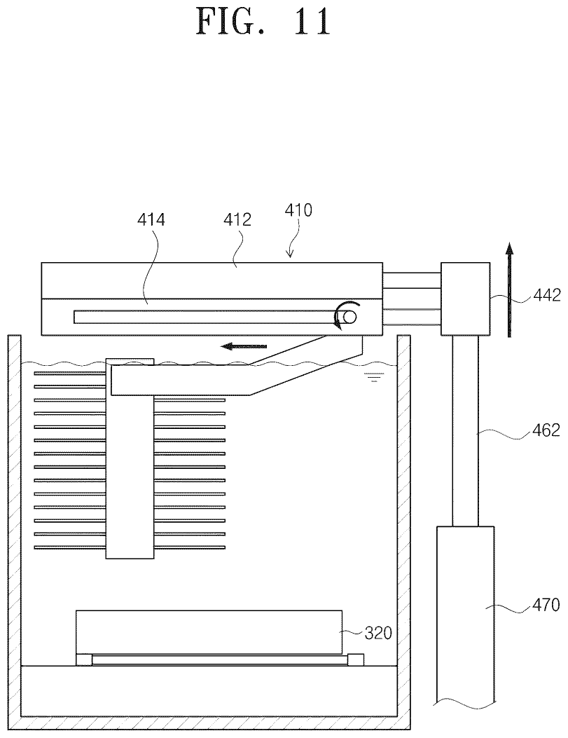

FIG. 11 to FIG. 13 schematically show a process in which the second posture changing step of FIG. 4 is performed in the second rinse bath.

Referring to FIG. 11, the second posture changing step S40 is also made in the treatment bath 310, similar to the first posture changing step S20, and is performed with the substrates W immersed in the treatment liquid accommodated in the treatment bath 310.

At the point in time of end of the substrate transferring step S30, the substrates W gripped by the gripping unit 420 in the treatment bath 310 are in the horizontal posture (the upper surfaces or the lower surfaces of the substrates W are parallel with the ground). A process of changing the posture of the substrates W from the horizontal posture to the vertical posture is performed to put the substrates W down on the supporting unit 320 of the treatment bath 310.

Since the second posture changing step S40, on the contrary to the first posture changing step S20 that changes the posture of the substrates W from a vertical posture to a horizontal posture, is a step of changing the posture of the substrates W from a horizontal posture to a vertical posture, the actuating order, movement direction, and rotation direction of the actuating unit 430 in the second posture changing step S40 are made opposite to those in the first posture changing step S30.

Referring to FIGS. 11 to 13, the posture of the substrates W is changed by rotation of the gripping unit 420. In order to prevent the gripping unit 420 or the substrates W from colliding with the floor of the treatment bath 310 in the rotation process, the elevation actuating unit 464 can move the body 410 vertically upward before rotation of the gripping unit 420.

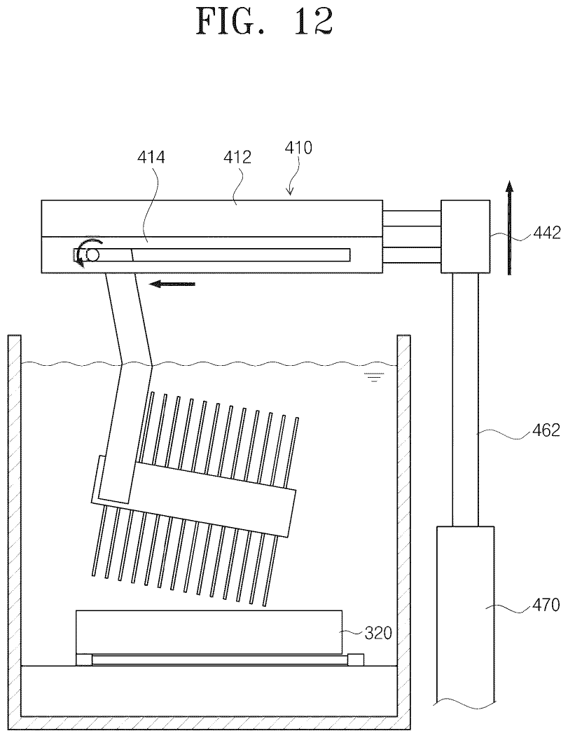

The rotation actuator 454 rotates the rotary shaft 452, and accordingly, the gripping unit 420 fixedly coupled to the rotary shaft 452 is rotated. The rotation direction of the rotary shaft 452, as shown in FIG. 12, is opposite to the rotation direction of the rotary shaft 452 in the first posture changing step S20.

In this process, the gripping unit 420 is also horizontally moved. The horizontal actuator 442 horizontally moves the rotary shaft 452 along the guides 418. Selectively, the body 410 may be moved up through the elevation actuator 464.

As the rotary shaft 452 is rotated 90 degrees, posture changing of the substrates W from the horizontal posture to the vertical posture is finished.

After rotation is finished, as in FIG. 12, the body 410 is moved downward by the elevation actuator 464 and the substrates W can be supported by the supporting unit 320.

As shown in FIG. 11 to FIG. 13, in the process of changing the posture of the substrates W from the vertical posture to the horizontal posture, the actuating unit 430 is not immersed in the treatment liquid accommodated in the treatment bath 310.

The difference between the point in time of end of rotation of the substrates W and the point in time of end of horizontal movement of the substrates W may be a set time or less. For example, the two points in time may be the same points in time. That is, rotation of the substrates W by the rotation actuator 454 may be finished simultaneously with end of horizontal movement of the substrates W.

The substrates W can be treated in the second rinse bath 142b after the second posture changing step S40. For example, the substrates W can be rinsed by a rinse solution including water in the second rinse bath 142b.

Referring to FIG. 1 again, the rinsed substrates W are moved to the posture changing unit 150 and are transferred to a standby chamber 210 in a horizontal posture by a single-type transfer robot 156, and a single-type treating step can be performed. In the single-type treating step, a single substrate W in a horizontal posture can be performed. The single-type treating step may include a liquid treating step of performing liquid treatment on substrates W in a single type and a drying step of drying substrates W in a single type. The liquid treating step can be performed in the liquid treatment chamber 230 when substrates W temporarily kept in the standby chamber 210 are transferred to the liquid treatment chamber 230. The drying step can be performed in the drying chamber 240 when the substrates W liquid-treated in the liquid treating step are transferred to the drying chamber 240. The substrates W that have undergone the single-type treating step are transferred to the buffer unit 250 and then can be transferred to the conveying container F placed in the second load port unit 270 by a second transfer robot 262 of a second transfer chamber 260, and a transfer device such as an OHT can grip and unload the conveying container F placed in the second load port unit 270 from the apparatus 10 of processing a substrate. Detailed description of this process is omitted.

According to the embodiment describe above, since the second batch transfer unit 142c changes the posture of substrates W immersed in treatment liquid, it is possible to maintain wettability of the substrates W as high as possible and prevent generation of a water mark due to drying of the substrates W. Accordingly, it is possible to minimize contamination of the substrates W when treating the substrates W.

Further, since the actuating unit 430 is not immersed in the treatment liquid accommodated in the treatment bath 310 in the posture changing process, it is possible to minimize production of particles due to friction that may be generated in the actuating process of the actuating unit 430. Accordingly, it is possible to minimize contamination of treatment liquid due to particles and minimize contamination of substrates in the process of changing the posture of the substrates W.

Further, since horizontal movement and elevation movement accompany when the gripping unit 420 is rotated in the posture changing process, it is possible to obtain the effect that the rotation center of a plurality of substrates is positioned not on the rotary shaft 452, but around the plurality of substrates W. Accordingly, even though substrates W are changed in posture in treatment liquid, it is possible to minimize an increase of use of a space for changing the posture and minimize an increase of the receiving space 316.

Since an increase of the size of the receiving space 316 in which substrates are treated is minimized, there is an effect that an increase of the amount of treatment liquid that should be accommodated in the receiving space 316 to treat substrates W is minimized and it is easy to adjust the temperature of the treatment liquid accommodated in the receiving space 316. Further, it is possible to minimize an increase of the amount of treatment liquid that should be supplied to the receiving space 316 to treat substrates W. Accordingly, it is possible to efficiently perform liquid treatment on substrates.

Unlike the embodiment described above, the second batch transfer unit 142c may further include a component such as a cover or a housing that surrounds the actuating unit 430 to prevent particles, which are produced in the actuating process of the actuating unit 430, from contaminating a treatment bath.

In the embodiment described above, it was shown and described that the second batch transfer unit 142c performs posture changing. However, unlike this, the configuration of the second batch transfer unit 142c can also be applied to another transfer unit that immerses and treats substrates in treatment liquid.

Referring to FIG. 1 again, after pure water treatment is finished, the second transfer unit 134 can unload and transfer substrates W to the posture changing unit 151 with the inner bath 552 filled with pure water.

The posture changing unit 150 can change the posture of substrates W. The posture changing unit 150 can change substrates W in a vertical posture to a horizontal posture. The a posture changing unit 150 can change the posture of the substrates W changed into a vertical posture at the batch treatment unit 140 such that the substrates W can be post-treated in the single treatment chambers 230 and 240 that treat substrates W for a single sheet of substrate W in a horizontal posture. The posture changing unit 150 may be disposed between the batch treatment unit 140 and the second process performing part 200.

The posture changing robot 156 may be disposed at a side of the posture changing bath 151. The posture changing robot 156 may be disposed between the posture changing bath 151 and the standby chamber 210 to be described below.

The posture changing robot 156 can change the posture of substrates W from a vertical posture to a horizontal posture in the posture changing bath 151 and transfer the substrates W changed into the horizontal posture to the standby chamber 210 of the second process performing part 200.

The second process performing part 200 can treat the substrates W treated at the first process performing part 100. The second process performing part 200 can treat the substrates W treated at the first process performing part 100 and perform liquid treatment or drying treatment on the substrates W in a single type.

The second process performing part 200 may include a standby chamber 210, a first transfer chamber 220, a liquid treatment chamber 230, a drying chamber 240, a buffer unit 250, a second transfer chamber 260, and a second load port unit 270. The liquid treatment chamber 230 and the drying chamber 240 both may be provided as single-type treatment chambers that treat one sheet of substrate W at each time.

The longitudinal direction of the first transfer chamber 220 is disposed in parallel with the first direction. The liquid treatment chamber 230 and the drying chamber 240 are disposed at a side of the first transfer chamber 220. The liquid treatment chamber 230 and the drying chamber 240 are arranged in the first direction. A plurality of liquid treatment chambers 230 may be provided and stacked in the up-down direction. Further, a plurality of drying chambers 240 may be provided and stacked in the up-down direction. According to an example, the drying chamber 240 is disposed close to the first process performing part 100 in comparison to the liquid treatment chamber 230. The standby chamber 210 and the buffer unit 250 are disposed at another side of the first transfer chamber 220. The standby chamber 210 and the buffer unit 250 are arranged in the first direction. The standby chamber 210 is disposed close to the first process performing part 100 in comparison to the buffer unit 250.

The second transfer chamber 260 is disposed opposite to the first transfer chamber 220 with the standby chamber 210 and the buffer chamber 250 therebetween. Further, the second load port unit 270 is disposed at a side of the first transfer chamber 220. Due to the disposition described above, the drying chamber 240, the first transfer chamber 220, the standby chamber 210, the second transfer chamber 260, and the second load port unit 270 are sequentially arranged in the second direction.

The standby chamber 210 can provide a storage space in which substrates W are temporarily kept. The standby chamber 310 may be disposed on the transfer path on which the substrates W treated at the batch treatment unit 140 are changed in posture by the posture changing robot 156 at the posture changing unit 150 and transferred to the single-type treatment chambers 230 and 240. That is, the buffer chamber 210 may be disposed on the transfer path of substrates W that are transferred between the batch treatment unit 140 and the single-type treatment chambers 230 and 240.

The standby chamber 210 temporarily keeps substrates W. Further, the standby chamber 210 keeps substrates W transferred by the posture changing robot in a wet state.

While substrates W stand by in the standby chamber 210, wetting liquid is supplied to the substrates W, thereby maintaining a liquid film of the wetting liquid on the substrates W. This prevents the substrates W from naturally dried before the substrates W are transferred to the single-type treatment chambers 230 and 240.

The substrates W with the liquid film maintained can be unloaded from the standby chamber 210 by the first transfer robot 222 to be described below. The substrates W unloaded from the standby chamber 210 can be transferred to the single-type chambers 230 and 240 by the first transfer robot 222.

The first transfer chamber 220 may include a first transfer robot 222 and a transfer rail 223. The first transfer robot 222 can move along the transfer rail 223. The longitudinal direction of the transfer rail 223 may be parallel with the first direction X.

The liquid treatment chamber 230 can rotate the posture of substrates W and can treat substrates W by supplying treatment liquid to rotating substrates W. Substrates W can be treated one sheet by one sheet in the liquid treatment chamber 230. The treatment liquid that is supplied in the liquid treatment chamber 230 may be an organic solvent. For example, the treatment liquid that is supplied in the liquid treatment chamber 230 may be isopropyl alcohol (IPA). In the liquid treatment chamber 230, it is possible to supply an organic solvent to rotating substrates W and dry the substrates W by rotating the substrates W. Unlike, an organic solvent is supplied to rotating substrates W in the liquid treatment chamber 230, the substrates W are transferred to the drying chamber 240 to be described below in the wet state by the organic solvent, and the substrates W can be dried in the drying chamber 240.

The drying chamber 240 can remove an organic solvent remaining on substrates W using a drying fluid G in a supercritical state. The drying chamber 240 may be a high-pressure chamber that removes an organic solvent remaining on substrates W using supercritical fluid. The drying fluid may be carbon dioxide (CO₂).

The substrates W treated in the single-type treatment chambers 230 and 240 can be transferred to the buffer unit 250 by the first transfer robot 222. The buffer unit 250 may be disposed between the first transfer chamber 220 and the second transfer chamber 260. The buffer unit 250 may be disposed between the single-type treatment chambers 230 and 240 and the second load port unit 270.

The buffer unit 250 can provide a space in which substrates W are temporarily stored and kept, similar to the standby chamber 210. For example, the buffer unit 250 can temporarily keep substrates W treated in the liquid treatment chamber 230 and/or the drying chamber 240 that are single-type treatment chambers.

The second transfer chamber 260 may be disposed between the buffer unit 250 and the second load port unit 270. The second transfer unit 262 can be provided in the second transfer chamber 260. The second transfer robot 262 can transfer the substrates W accommodated in the buffer unit 250 after treated to a conveying container F.

The hand of the second transfer robot 262 may be a single-type hand that transfers substrates W one sheet by one sheet. The transfer hand of the second transfer robot 262 may be provided to be able to move in the first direction X, the second direction Y, and the third direction Z. Further, the transfer hand of the second transfer robot 262 may be provided to be rotatable around the third direction Z.

The second load port unit 270 may include at least one or more load ports. A conveying container F in which a plurality of substrates W can be accommodated may be placed in the second load port unit 270. For example, substrates W treated at the first process performing part 100 and the second process performing part 200 can be accommodated in the conveying container F that is placed in the second load port unit 270. Only substrates W treated at the first process performing part 100 and the second process performing part 200 can be accommodated in the conveying container F that is placed in the second load port unit 270. That is, the second load port unit 270 can perform the function of unloading treated substrates W from the apparatus of processing a substrate.

The second transfer robot 262 can load treated substrates into the container F placed in the load port of the second load port unit 270. The container F can be transferred out of the apparatus 10 of processing a substrate by the item transfer device (e.g., an OHT).

A control unit 600 can control the apparatus 10 of processing a substrate. For example, the control unit 600 can control the components of the apparatus 10 of processing a substrate. For example, the control unit 600 can control the apparatus 10 of processing a substrate such that the apparatus 10 of processing a substrate can perform a process of treating substrates W.

For example, the control unit 600 can control at least one or more of the first load port unit 110, the index chamber 120, the transfer unit 130, the batch treatment unit 140, the posture changing unit 150, the buffer chamber 210, the first transfer chamber 220, the liquid treatment chamber 230, the drying chamber 240, the second transfer chamber 260, and the second load port unit 270.

Further, the control unit 600 may include: a process controller that is a microprocessor (computer) that performs control of the apparatus 10 of processing a substrate; a user interface that is a keyboard through which an operator performs command input operation, etc. to manage the apparatus 10 of processing a substrate, a display that visualizes and displays the operation situation of the apparatus 10 of processing a substrate, etc.; and a memory that stores a control program for performing treatment, which is performed in the apparatus 10 of processing a substrate, under control of the process controller, a program for performing treatment on each component in accordance with various data and treatment conditions, that is, a treatment recipe. Further, the user interface and the memory may be connected to the process controller. The treatment recipe may be stored in a memory medium of the memory unit and the memory medium may be a hard disk and may be a portable disc such as a CD-ROM and a DVD, and a semiconductor memory such as a flash memory.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1.-10. (canceled)

11. A method of processing a substrate, the method comprising:
a treating step of performing liquid treatment by immersing a plurality of substrates in a vertical posture in a treatment bath accommodating treatment liquid; and
a posture changing step of changing a posture of the plurality of substrates from the vertical posture to a horizontal posture after the treating step,
wherein, in the posture changing step, when the plurality of substrates is rotated from the vertical posture to the horizontal posture, horizontal movement of the plurality of substrates is also performed.

12. The method of claim 11, wherein vertical movement of the plurality of substrates accompanies in the posture changing step.

13. The method of claim 11, wherein posture changing of the plurality of substrates is made in the treatment bath in the posture changing step.

14. The method of claim 13, wherein the posture changing step is made with the plurality of substrates immersed in the treatment liquid.

15. The method of claim 13, wherein the posture changing step is made while the actuation unit performing the posture changing is not immersed in the treatment liquid.

16. The method of claim 11, further comprising a substrate transferring step of transferring the plurality of substrates after the posture changing step.

17.-20. (canceled)
